(19) United States
(12) Patent Application Publication
(10) Pub. No.: US 2013/0134879 A1
(43) Pub. Date: May 30, 2013

(54) Luminaire

(71) Applicants: Yumi Hanyuda, Yokosuka-shi (JP); Takayoshi Moriyama, Yokosuka-shi (JP); Hirokazu Otake, Yokosuka-shi (JP)

(72) Inventors: Yumi Hanyuda, Yokosuka-shi (JP); Takayoshi Moriyama, Yokosuka-shi (JP); Hirokazu Otake, Yokosuka-shi (JP)

(73) Assignee: TOSHIBA LIGHTING & TECHNOLOGY CORPORATION, Yokosuka-shi (JP)

(21) Appl. No.: 13/595,376

(22) Filed: Aug. 27, 2012

(30) Foreign Application Priority Data
Nov. 30, 2011 (JP) 2011-262840

(51) Int. Cl. H05B 37/02; H01L 33/64; H05B 37/00

(52) U.S. Cl. 315/112; 315/245; 315/240

(57) ABSTRACT

According to one embodiment, a luminaire includes a housing, a cable run, and a noise filter circuit. A lighting-circuit-integrated lamp is arranged in the housing. The cable run is configured to supply an external power to the lighting-circuit-integrated lamp. The noise filter circuit is provided in the cable run and reduces a noise terminal voltage.

### INCORPORATION BY REFERENCE

The present invention claims priority under 35 U.S.C. §119 to Japanese Patent Application No. 2011-262840 filed on Nov. 30, 2011. The content of the application is incorporated herein by reference in their entirety.

### FIELD

Embodiments described herein relate generally to a luminaire using a lighting-circuit-integrated lamp.

### BACKGROUND

In the related art, there is a luminaire using a lighting-circuit-integrated lamp such as a bulb-shaped lamp having a built-in lighting circuit configured to turn ON a light source by inputting an external power supply together with, for example, a light source such as a fluorescent tube or an LED. The luminaire includes a housing configured to accommodate the lighting-circuit-integrated lamp, and a socket configured to connect the lighting-circuit-integrated lamp, a cable run configured to supply an external power to the lighting-circuit-integrated lamp through the socket, and the like are arranged in the housing.

A noise terminal voltage transmitted to a power supply line per lamp of the lighting-circuit-integrated lamp is within specs prescribed by Electrical Appliance and Material Safety Law and CISPR (International Special Committee on Radio Interference).

However, when the lighting-circuit-integrated lamp is arranged in the housing of the luminaire, a noise from the lighting-circuit-integrated lamp is transmitted from the cable run to the external power supply due to the presence of a stray capacitance between the lighting-circuit-integrated lamp and the housing, so that there is a probability that the noise terminal voltage may be out of specs.

It is an object of exemplary embodiments is to provide a luminaire which is capable of reducing a noise terminal voltage.

### BRIEF DESCRIPTION OF THE DRAWINGS

FIG. 1 illustrates a cross-sectional view of a luminaire according to an embodiment;

FIG. 2 illustrates a front view of the luminaire partly omitted; and

FIG. 3 illustrates a circuit diagram of a noise filter circuit of the luminaire.

### DETAILED DESCRIPTION

A luminaire of an embodiment includes a housing, a cable run, and a noise filter circuit. A lighting-circuit-integrated lamp is arranged in the housing. The cable run is configured to supply an external power to the lighting-circuit-integrated lamp. The noise filter circuit is provided in the cable run and reduces a noise terminal voltage.

Accordingly, since the luminaire using the lighting-circuit-integrated lamp is provided with the noise filter circuit in the cable run configured to supply the external power to the lighting-circuit-integrated lamp, a reduction of the noise terminal voltage may be expected.

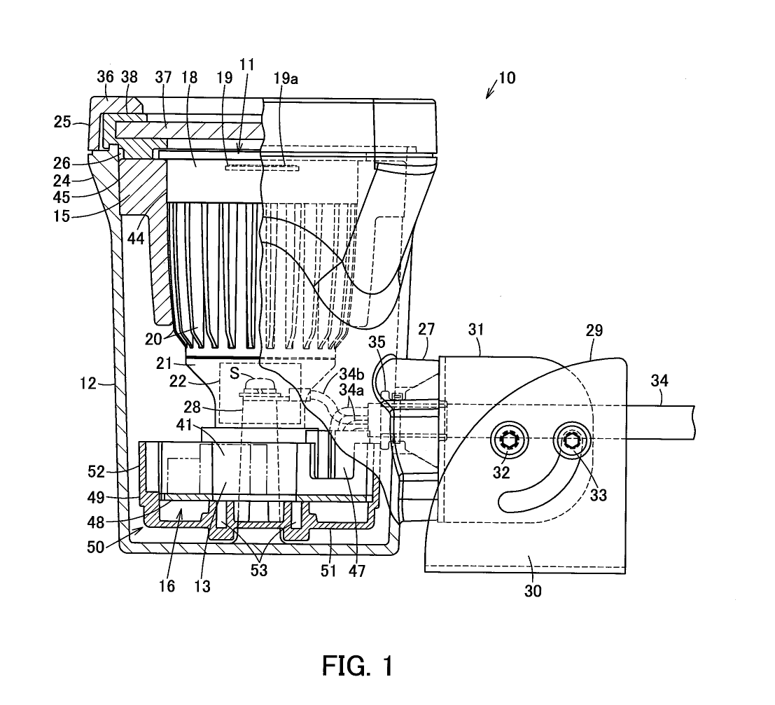

Referring now to FIG. 1 to FIG. 3, an embodiment will be described.

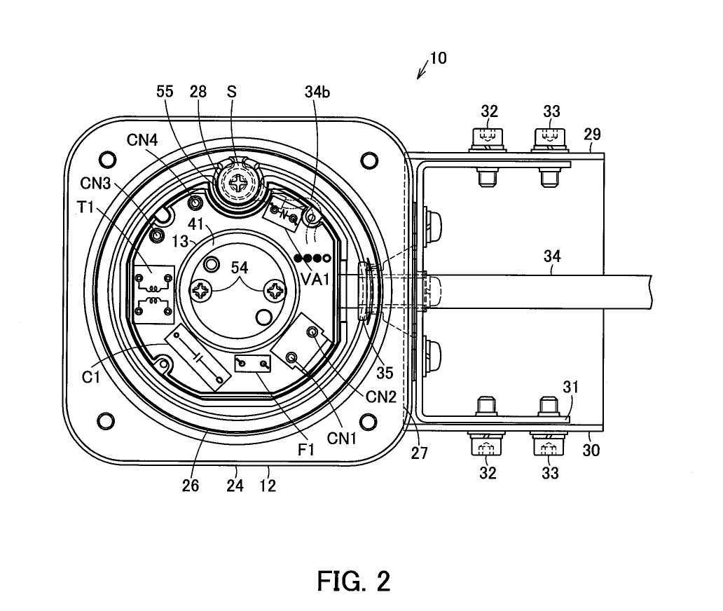

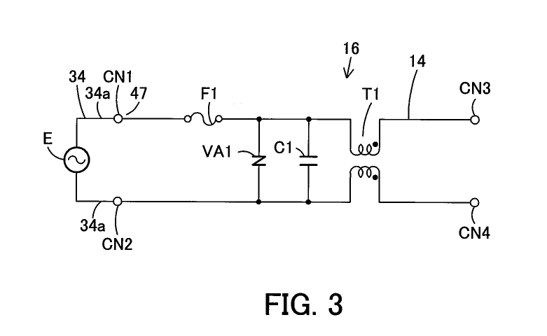

As illustrated in FIG. 1 and FIG. 2, a luminaire 10 is a waterproof apparatus, and includes a lighting-circuit-integrated lamp 11, a housing 12 configured to accommodate the lighting-circuit-integrated lamp 11 to be arranged therein, a socket 13 configured to connect the lighting-circuit-integrated lamp 11, a cable run 14 (see FIG. 3) configured to supply the external power to the lighting-circuit-integrated lamp 11 through the socket 13, a thermal conducting member 15 configured to connect the lighting-circuit-integrated lamp 11 and the housing 12 so as to allow thermal conduction, and a noise filter circuit 16 provided in the cable run 14.

The lighting-circuit-integrated lamp 11 includes, for example, a metallic cylindrical case 18, and a light-emitting portion 19 using a semiconductor light-emitting element such as an LED element 19a and an EL element as a light source is disposed at one end of the case 18. A plurality of fins 20 configured to radiate heat are disposed in the periphery of the case 18 so as to project radially.

A cylindrical cover 21 formed of an insulating material such as a synthetic resin is mounted on the other end of the case 18. The cover 21 is provided at a distal end side thereof with a connecting portion to be connected to the socket 13. The connecting portion may have any suitable form which achieves an electrical connection and a mechanical holding such as a form of a pair of projecting pins having an enlarged diameter portion at distal ends thereof or a form of a cap of Edison type.

A lighting circuit 22 configured to turn the light source ON is integrated at least in the cover 21 of the case 18 and the cover 21. The lighting circuit 22 includes, for example, a DC circuit configured to convert an AC power supply voltage which is the external power supply to a DC voltage, and a power conversion circuit including a switching element configured to convert the DC voltage converted by the DC circuit into a predetermined power supply voltage for turning the light source ON.

The housing 12 includes a cylindrical apparatus body 24 having a waterproof structure and opening only toward the front, and a front cover member 25 configured to demountably close the front side of the apparatus body 24.

The apparatus body 24 is formed of a metal such as aluminum, formed with an opening portion 26 on a front surface thereof and with a mounting portion 27 on the side surface thereof. Integrally formed within the apparatus body 24 is a boss 28 used for both grounding and positioning. An inner peripheral surface of the apparatus body 24 is formed with a plurality of flat portions together with the boss 28, and is formed into an irregular shape in the circumferential direction instead of a circular shape.

Mounted on the mounting portion 27 is a bracket 29 for installing the luminaire 10. The bracket 29 includes a fixed bracket 30 to be fixed to a location of installation such as a wall surface, and a movable bracket 31 to be mounted on the mounting portion 27. The fixed bracket 30 and the movable bracket 31 are rotatably coupled by a supporting point screw 32, and the fixed bracket 30 and the movable bracket 31 are fixed by an adjusting screw 33 after an angle adjustment of the movable bracket 31 with respect to the fixed bracket 30.

A cable 34 configured to supply the external power to the luminaire 10 is inserted through the mounting portion 27 via a packing 35. The cable 34 includes a pair of power cables 34a for the external power supply connected to the noise filter circuit 16 and one earth cable 34b connected by a screw S to the boss 28 for grounding.

The front cover member 25 includes an annular front frame 36, a translucent cover 37 formed of a transparent material such as glass or a synthetic resin into a disk shape and arranged inside the front frame 36, and an annular packing 38 interposed between the front frame 36 and the translucent cover 37. Then, the front cover member 25 is secured to the apparatus body 24 at a plurality of points by screw tightening, so that the apparatus body 24 and the front cover member 25 are attached in an air-tight manner by the intermediary of the packing 38.

The socket 13 includes a cylindrical socket body 41 connected by inserting a connecting portion of the lighting-circuit-integrated lamp 11. The socket body 41 is formed of an insulating material such as a synthetic resin and a pair of terminals to be electrically connected to the connecting portion of the lighting-circuit-integrated lamp 11 are arranged in the interior of the socket body 41. A mechanical holding structure of the connecting portion of the lighting-circuit-integrated lamp 11 may be provided on the socket body 41 or may be shared by the terminals.

The cable run 14 includes the noise filter circuit 16 interposed therein, and is configured by sections between a connecting portion (connector 47) of the noise filter circuit 16 to which the cable 34 is connected to the terminals of the socket 13.

The thermal conducting member 15 is formed of a material having insulating properties, thermal conductivity and resiliency such as silicone resin, and includes a cylindrical lighting-circuit-integrated lamp contact portion 44 attached tightly along the shape of an outer peripheral surface of the case 18 of the lighting-circuit-integrated lamp 11 and an apparatus body contact portion 45 to be attached tightly along the shape of an inner peripheral surface of the apparatus body 24 so as to project from the outer peripheral surface of the lighting-circuit-integrated lamp contact portion 44.

The noise filter circuit 16 is configured to reduce the noise terminal voltage to the side of the external power supply, and the circuit is configured as illustrated in FIG. 3. The power cables 34a and 34a of the cable 34 configured to supply an AC power supply E as the eternal power supply are connected to input ends CN1 and CN2 of the connector 47, and connected between the input ends CN1 and CN2 are a fuse F1 and a series circuit of a varistor VA1 against lightning surge. Connected in parallel to the varistor VA1 are a capacitor C1 configured to reduce the noise terminal voltage and an input side of a common mode choke T1. Output ends CN3 and CN4 are connected to the output side of the common mode choke T1, and a pair of the terminals of the socket 13 are connected to the output ends CN3 and CN4.

As illustrated in FIG. 1 and FIG. 2, the noise filter circuit 16 includes a disk-shaped substrate 48 and respective electronic components of the noise filter circuit 16 described above are mounted in a periphery of the substrate 48.

The noise filter circuit 16 is integrated into a circuit case 49 and is unified as a filter unit 50. The circuit case 49 is formed of an insulating material such as a synthetic resin, and includes an end surface wall potion 51 opposing the end surface of the apparatus body 24 and a side surface wall portion 52 opposing the inner peripheral surface of the apparatus body 24, and is opened toward the front. A plurality of mounting holes 53 are formed in a central area of the end surface wall potion 51. Then, the substrate 48 is accommodated and arranged in the circuit case 49 and the socket 13 is also arranged at a center in the circuit case 49. Screws 54 to be inserted from inside the socket 13 are tightened into the mounting holes 53 of the circuit case 49, whereby the socket 13, the substrate 48, and the circuit case 49 are tightened and fixed integrally and hence are unified. An outer peripheral surface of the side surface wall portion 52 of the circuit case 49 includes a depressed portion 55 fitted to the boss 28 of the apparatus body 24, and is formed into an irregular shape in the circumference direction so as to match the shape of the inner peripheral surface of the apparatus body 24 instead of a circular shape.

In order to assemble the luminaire 10, the filter unit 50 is inserted from the opening portion 26 of the apparatus body 24 and arranged in the apparatus body 24. At this time, the circuit case 49 of the filter unit 50 and the inner peripheral surface of the apparatus body 24 are fitted to each other only in a certain direction so that the depressed portion 55 and the boss 28 are fitted to each other, and in the fitted state, the rotation in the direction of rotation about an optical axis of the lighting-circuit-integrated lamp 11 is prohibited.

The cable 34 is drawn into the interior of the housing 12, the earth cable 34b is connected to the boss 28 with the screw S, and the power cables 34a are connected to the connector 47.

The thermal conducting member 15 is mounted on an outer periphery of the lighting-circuit-integrated lamp 11, the lighting-circuit-integrated lamp 11 is inserted into the apparatus body 24 from the side of the connecting portion, the connecting portion is connected to the socket 13, and the thermal conducting member 15 is brought into contact with the inner peripheral surface of the apparatus body 24.

The front cover member 25 is covered on the front surface of the apparatus body 24, and the front cover member 25 is fixed to the apparatus body 24 by tightening plurality of screws. Accordingly, the filter unit 50 and the lighting-circuit-integrated lamp 11 are clamped and held between the apparatus body 24 and the front cover member 25.

The luminaire 10 allows replacement of the lighting-circuit-integrated lamp 11 or replacement of the filter unit 50 by removing the front cover member 25 even after the assembly.

In the luminaire 10 configured as described above, the external power supply is distributed from the terminals of the socket 13 to the lighting-circuit-integrated lamp 11 via the noise filter circuit 16 by supplying the external power to the luminaire 10 through the cable 34. The external power supply converted into a DC voltage and converted into a predetermined power supply voltage by the lighting circuit 22 of the lighting-circuit-integrated lamp 11 is supplied to the light source, so that the light source is turned ON.

The light generated by the light source is irradiated from a front surface of the lighting-circuit-integrated lamp through the translucent cover 37 to the front of the luminaire 10.

The heat generated by lighting of the light source is transferred to the case 18 of the lighting-circuit-integrated lamp 11, and is conducted efficiently to the apparatus body 24 by the thermal conducting member 15 which is in contact respectively with the case 18 and the apparatus body 24, and is radiated to outside air from the apparatus body 24 and from the front frame 36 and the bracket 29 which are in contact with the apparatus body 24. Therefore, heat generated by the lighting-circuit-integrated lamp 11 accommodated in a sealed space in the housing 12 may be efficiently conducted to the housing 12 by the thermal conducting member 15 and radiated from the housing 12, so that excessive temperature rise of the lighting-circuit-integrated lamp 11 may be inhibited.

The noise generated by the lighting circuit 22 of the lighting-circuit-integrated lamp 11 may be transmitted to the cable run 14 due to the stray capacitance formed between the lighting-circuit-integrated lamp 11 and the housing 12 when the lighting-circuit-integrated lamp 11 is accommodated and arranged in the housing 12. In this case, reduction of the noise transmitted through the cable run 14 by the noise filter circuit 16 provided in the cable run 14 and lowering of the noise terminal voltage transmitted from the luminaire 10 to the external power supply side are achieved.

Since the noise filter circuit 16 is integrated into the circuit case 49 having insulating properties and is unified as the filter unit 50, assembly to the housing 12 is easily achieved, and the insulating properties with respect to the housing 12 may easily be maintained.

Incidentally, the noise terminal voltage transferred to the external power supply side varies in accordance with the type of the lighting-circuit-integrated lamp 11, the shapes of the lighting-circuit-integrated lamp 11 and the housing 12, and the thermal conducting member 15 and the like. Therefore, the noise filter circuit 16 is preferably capable of reducing noises of any frequencies . However, in order to do so, upsizing or cost increase may result. Accordingly, by configuring the noise filter circuit 16 to be replaceable with respect to the housing 12, suitable noise filter circuits 16 may be combined to each of the luminaires 10.

Since the socket 13 and the noise filter circuit 16 are integrally unified by the filter unit 50, the cable run 14 configured to supply the external power to the lighting-circuit-integrated lamp 11 and the noise filter circuit 16 may be unified, so that a downsized configuration is achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A luminaire comprising:
a housing in which a lighting-circuit-integrated lamp is arranged therein;
a cable run configured to supply an external power to the lighting-circuit-integrated lamp; and
a noise filter circuit configured to reduce a noise terminal voltage and provided in the cable run.

2. A luminaire comprising:
a lighting-circuit-integrated lamp;
a housing in which the lighting-circuit-integrated lamp is arranged therein;
a cable run configured to supply an external power to the lighting-circuit-integrated lamp; and
a noise filter circuit configured to reduce a noise terminal voltage and provided in the cable run.

3. The luminaire according to claim 1, wherein the noise filter circuit is arranged in the housing.

4. The luminaire according to claim 1, wherein the noise filter circuit is demountably arranged in the housing.

5. The luminaire according to claim 1, wherein the noise filter circuit includes a capacitor configured to reduce the noise terminal voltage and a common mode choke.

6. The luminaire according to claim 1, comprising:
a socket configured to connect the lighting-circuit-integrated lamp, wherein
the socket and the noise filter circuit are integrally unified.

7. The luminaire according to claim 6, wherein the cable run is integrally unified with the socket and the noise filter circuit.

8. The luminaire according to claim 1, comprising:
a circuit case having insulating properties configured to accommodate the noise filter circuit and arranged in the housing.

9. The luminaire according to claim 8, further comprising:
a socket configured to connect the lighting-circuit-integrated lamp, wherein
the noise filter circuit includes a substrate and an electronic component to be mounted in a peripheral portion of the substrate, and
the socket is arranged at a center of the substrate, and the socket is fixed to the circuit case with a screw via the substrate.

10. The luminaire according to claim 1, further comprising:
a connector arranged in the housing and to which a cable for supplying the external power is connected; and
a socket to which the lighting-circuit-integrated lamp is connected, wherein
the cable run is formed between the connector and the socket.

11. The luminaire according to claim 1, wherein the housing includes an apparatus body opening only toward the front, a front cover member configured to close the front side of the apparatus body, and a packing to be interposed between the apparatus body and the front cover member, and is formed to have a waterproof structure.

12. The luminaire according to claim 1, further comprising: a thermal conducting member configured to connect the lighting-circuit-integrated lamp and the housing so as to allow thermal conduction.

13. The luminaire according to claim 12, wherein the thermal conducting member is formed of a material having insulating properties, thermal conductivity, and resiliency.

14. The luminaire according to claim 1, wherein the lighting-circuit-integrated lamp includes a light-emitting portion using a semiconductor light-emitting element, and a lighting circuit configured to convert the external power supplied from the cable run and supply the converted external power to the semiconductor light-emitting element.

15. The luminaire according to claim 14, wherein the semiconductor light-emitting element is an LED element.
